(19) United States
(12) Patent Application Publication
(10) Pub. No.: US 2025/0072120 A1
(43) Pub. Date: Feb. 27, 2025

(54) HIGH-VOLTAGE JUNCTION TERMINAL STRUCTURE WITH REDUCED TRIGGERING VOLTAGE OF ELECTROSTATIC DISCHARGE AND HIGH-VOLTAGE TRANSISTOR WITH INCREASED TRIGGER VOLTAGE OF ELECTROSTATIC DISCHARGE

(71) Applicant: Nuvoton Technology Corporation, Hsinchu Science-based Park (TW)

(72) Inventor: Po-An CHEN, Hsinchu Science-based Park (TW)

(21) Appl. No.: 18/780,944

(22) Filed: Jul. 23, 2024

(30) Foreign Application Priority Data
Aug. 23, 2023 (TW) 112131630

(51) Int. Cl. H01L 27/02

(52) U.S. Cl. CPC H01L 27/0255

(57) ABSTRACT

A semiconductor structure includes a first well, a second well, a first doping region, a second doping region, a field oxide layer, a third well, and a fourth well. The first well is N-type. The second well is P-type, adjacent to the first well and in contact with the first well at an interface. The first doping region is N-type and deposited in the first well. The second doping region is P-type and deposited in the second well. The field oxide layer is formed in the first well and deposited between the first doping region and the second doping region. The third well is N-type, formed in the first well, and deposited below the field oxide layer. The fourth well is N-type, formed in the first well, and deposited below the field oxide layer.

### CROSS REFERENCE TO RELATED APPLICATIONS

This application claims priority of Taiwan Patent Application No. 112131630, filed on Aug. 23, 2023, the entirety of which is incorporated by reference herein.

### BACKGROUND OF THE INVENTION

### Field of the Invention

The present invention is generally related to a high-voltage junction terminal structure for isolating circuits in a high-side region from circuits in a low-side region, and more particularly it is related to a high-voltage junction terminal structure with a reduced triggering voltage of electrostatic discharge and a high-voltage transistor with an increased trigger voltage of electrostatic discharge.

### Description of the Related Art

FIG. 1 is a schematic diagram illustrating a high voltage integrated circuit. As shown in FIG. 1, the high-voltage integrated circuit 100 includes a low-side driving circuit 110, a level-shift circuit 120, a high-side driving circuit 130, a high-side transistor Q1 and a low-side transistor Q2. The low-side driving circuit 110 controls the low-side transistor Q2 based on the input signal SIN to control the high-side transistor Q1 through the level-shift circuit 120 and the high-side circuit 130. The low-side driving circuit 110 is powered by a low voltage VD and a ground terminal GND.

The high-side driving circuit 130 is powered by the first high voltage VB and the floating voltage VS. The first high voltage VB exceeds the second high voltage HV. The high-side transistor Q1 and the low-side transistor Q2 are not turned on at the same time to generate the floating voltage VS. The level-shift circuit 120 includes a first N-type transistor N1, a second N-type transistor N2, a first resistor R1, and a second resistor R2, for converting the driving signal generated by the low-side driving circuit 110 (i.e., ranging from the low voltage VD to the ground terminal GND) into the voltage level of the high-side driving circuit 130 (i.e., ranging from the first high voltage VB to the floating voltage VS). In order to isolate the low-side driving circuit 110 and the high-side driving circuit 130, the high-voltage integrated circuit 100 further includes a junction diode JD, which is the parasitic diode of a high-voltage junction termination structure. The cathode node NC of the junction diode JD is coupled to the first high voltage VB, and the anode node NA of the junction diode JD is coupled to the ground terminal GND.

Since the junction diode JD occupies a larger circuit area than the first N-type transistor N1 and the second N-type transistor N2 do, when an electrostatic discharge event occurs at the first high voltage VB, electrostatic charge expelled through the junction diode JD helps to protect the high-voltage integrated circuit 100 from burning out. Since the junction diode JD, the first N-type transistor N1, and the second N-type transistor N2 are adjacent to one another in the circuit layout and have similar structures, it is possible for them to be used to expel electrostatic charge. In order to avoid damage caused by the first N-type transistor N1 or the second N-type transistor N2 being turned on when an electrostatic discharge event occurs, it is necessary to ensure that the electrostatic charge is expelled to the ground terminal GND through the junction diode JD.

### BRIEF SUMMARY OF THE INVENTION

The present invention proposes a semiconductor structure of a high-voltage junction terminal structure, which helps to reduce the breakdown voltage of the parasitic diode of the high-voltage junction terminal structure by inserting a well with a higher concentration into the well of the high-voltage junction terminal structure, leading to the electrostatic charge being discharged to the ground through the parasitic diode of the high-voltage junction terminal structure. The present invention further proposes transistors adjacent to the high-voltage junction terminal structure. By inserting a gap into the well of the transistors adjacent to the high-voltage junction terminal structure, the breakdown voltage of the transistors is increased, thereby promoting the parasitic diode of the high-voltage junction termination structure, which is adjacent to the transistors and has a lower breakdown voltage, to preferentially break down to expel the electrostatic charges.

In an embodiment, a semiconductor structure is provided, which comprises a first well, a second well, a first doping region, a second doping region, a field oxide layer, a third well, and a fourth well. The first well is doped with an N-type dopant. The second well is doped with a P-type dopant. The second well is adjacent to the first well. The second well is in contact with the first well at an interface. The first doping region is doped with the N-type dopant. The first doping region is deposited in the first well. The second doping region is doped with the P-type dopant. The second doping region is deposited in the second well. The field oxide layer is formed in the first well. The field oxide layer is deposited between the first doping region and the second doping region. The third well is doped with the N-type dopant. The third well is formed in the first well. The third well is deposited below the field oxide layer. The fourth well is doped with the N-type dopant. The fourth well is formed in the first well. The fourth well is deposited below the field oxide layer. The third well and the fourth well are configured to reduce the breakdown voltage of the interface.

According to an embodiment of the present invention, semiconductor elements in the first region are powered by a first high voltage and a first low voltage, and semiconductor elements in the second region are powered by a second high voltage and a second low voltage. The first high voltage exceeds the first low voltage, and the second high voltage exceeds the second low voltage. The first high voltage exceeds the second high voltage. The second low voltage does not exceed the first low voltage.

According to an embodiment of the present invention, the first well has a first depth, and the third well has a second depth. The second depth does not exceed the first depth.

According to an embodiment of the present invention, the semiconductor structure further comprises a gate oxide layer and a gate electrode. The gate oxide layer covers on the interface and deposited between the first doping region and the second doping region. The gate electrode covers on the field oxide layer and the gate oxide layer and is in contact with the gate oxide layer. At least part of the gate oxide electrode covers the field oxide layer.

According to an embodiment of the present invention, the third well has a first width. The fourth well has a second width. The first width is not less than the second width.

According to an embodiment of the present invention, there is a first space between the third well and the fourth well. The third well is adjacent to the first doping region. The fourth well is adjacent to the gate electrode. The first space is not less than zero.

According to an embodiment of the present invention, there is a second space between the fourth well and the gate electrode. The second space is not less than zero.

According to another embodiment of the present invention, the semiconductor structure further comprises a fifth well. The fifth well is doped with the N-type dopant, formed in the first well, and deposited below the field oxide layer. The fifth well is deposited between the fourth well and the gate electrode. The fifth well has a third width. The first width is not less than the second width, and the second width is not less than the third width.

According to an embodiment of the present invention, the semiconductor structure further comprises a sixth well and a seventh well. The sixth well is doped with the P-type dopant, formed in the second well, and adjacent to the second doping region. The seventh well is doped with the P-type dopant, formed in the second well, and deposited between the sixth well and the gate electrode. The sixth well and the seventh well are configured to reduce the breakdown voltage of the interface.

According to an embodiment of the present invention, there is a third space between the sixth well and the seventh well. The third space is not less than zero.

According to an embodiment of the present invention, the sixth well has a fourth width. The seventh well has a fifth width. The fourth width is not less than the fifth width.

According to another embodiment of the present invention, the semiconductor structure further comprises an eighth well. The eighth well is doped with the P-type dopant, formed in the second well, and deposited between the seventh well and the gate electrode. The eighth well has a sixth width. The fifth width is not less than the sixth width.

According to an embodiment of the present invention, there is a fifth space between the eighth well and the gate electrode. The fifth space exceeds zero.

In another embodiment of the present invention, a semiconductor structure comprises a substrate, a first well, a second well, a third well, a first doping region, a second doping region, a third doping region, and a field oxide layer. The first well is doped with an N-type dopant and formed in the substrate. The second well is doped with the N-type dopant, formed in the substrate, and adjacent to the first well. There is a first space between the first well and the second well. The third well is doped with a P-type dopant, adjacent to the second well, and in contact with the second well at an interface. The first doping region is doped with the N-type dopant and formed in the first well. The second doping region is doped with the P-type dopant and formed in the third well. The third doping region is doped with the N-type dopant, formed in the third well, and deposited between the first doping region and the second doping region. The field oxide layer covers the first well, the second well, and the substrate and is deposited between the first doping region and the third doping region. The first space is configured to increase the breakdown voltage of the interface.

According to an embodiment of the present invention, the semiconductor structure forms a transistor.

According to an embodiment of the present invention, the semiconductor structure further comprises a gate oxide layer and a gate electrode. The gate oxide layer covers the interface and is deposited between the first doping region and the third doping region. The gate electrode covers the field oxide layer and the gate oxide layer and is in contact with the gate oxide layer. At least part of the gate electrode covers the field oxide layer. The semiconductor forms a transistor.

According to an embodiment of the present invention, the semiconductor structure further comprises a fourth well. The fourth well is doped with the N-type dopant, formed in the substrate, and deposited between the second well and the third well. The fourth well is in contact with the third well at the interface. There is a second space between the fourth well and the second well.

According to an embodiment of the present invention, the second space exceeds the first space.

According to another embodiment of the present invention, the second space is equal to the first space.

According to another embodiment of the present invention, there is a gap between the second well and the fourth well. The width of the gap is the second space. There is a third space between the gap and the gate electrode. The third space exceeds zero.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic diagram illustrating a high voltage integrated circuit;

FIG. 2 is a cross-sectional view illustrating a semiconductor structure in accordance with an embodiment of the present invention;

FIG. 3 is a cross-sectional view illustrating a semiconductor structure in accordance with another embodiment of the present invention;

FIG. 4 is a cross-sectional view illustrating a semiconductor structure in accordance with yet another embodiment of the present invention;

FIG. 5 is a cross-sectional view illustrating a semiconductor structure in accordance with yet another embodiment of the present invention;

FIG. 6 is a cross-sectional view illustrating a semiconductor structure in accordance with yet another embodiment of the present invention; and

FIG. 7 is a cross-sectional view illustrating a semiconductor structure in accordance with yet another embodiment of the present invention.

### DETAILED DESCRIPTION OF THE INVENTION

The following description is made for the purpose of illustrating the general principles of the disclosure and should not be taken in a limiting sense. The scope of the disclosure is determined by reference to the appended claims.

In the following detailed description, for purposes of explanation, numerous specific details and embodiments are set forth to provide a thorough understanding of the present disclosure. The use of like and/or corresponding numerals in the drawings of different embodiments does not suggest any correlation between different embodiments.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In addition, in this specification, relative spatial expressions are used. For example, “lower”, “bottom”, “higher” or “top” are used to describe the position of one element relative to another. It should be appreciated that if a device is flipped upside down, an element that is “lower” will become an element that is “higher”.

It should be understood that, the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, or section. Thus, a first element, component, region, layer, portion or section in the specification could be termed a second element, component, region, layer, portion or section in the claims without departing from the teachings of the present disclosure.

It should be understood that this description of the exemplary embodiments is intended to be read in connection with the accompanying drawings, which are to be considered part of the entire written description. The drawings are not drawn to scale. In addition, structures and devices are shown schematically to simplify the drawing.

The terms “approximately”, “about” and “substantially” typically mean a value is within a range of +/−20% of the stated value, more typically a range of +/−10%, +/−5%, +/−3%, +/−2%, +/−1% or +/−0.5% of the stated value. The stated value of the present disclosure is an approximate value. Even there is no specific description, the stated value still includes the meaning of “approximately”, “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In the drawings, similar elements and/or features may have the same reference number. Various components of the same type can be distinguished by adding letters or numbers after the component symbol to distinguish similar components and/or similar features.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

It should also be noted that the present disclosure presents embodiments of a semiconductor device and may be included in an integrated circuit (IC) such as a microprocessor, memory device, and/or other device. The IC may also include various passive and active microelectronic devices, such as thin film resistors, other capacitor (e.g. metal-insulator-metal capacitor, MIMCAP), inductors, diodes, metal-oxide-semiconductor field effect transistors (MOSFETs), complementary MOS (CMOS) transistors, bipolar junction transistors (BJTs), laterally diffused MOS (LDMOS) transistors, high power MOS transistors, or other types of transistors. One of ordinary skill may recognize that the high-voltage semiconductor devices may be used in other type of semiconductor elements.

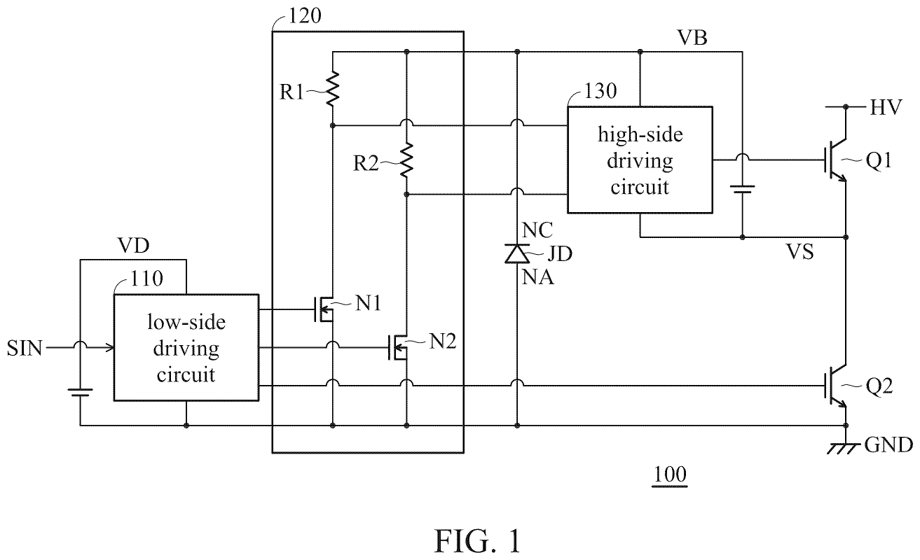

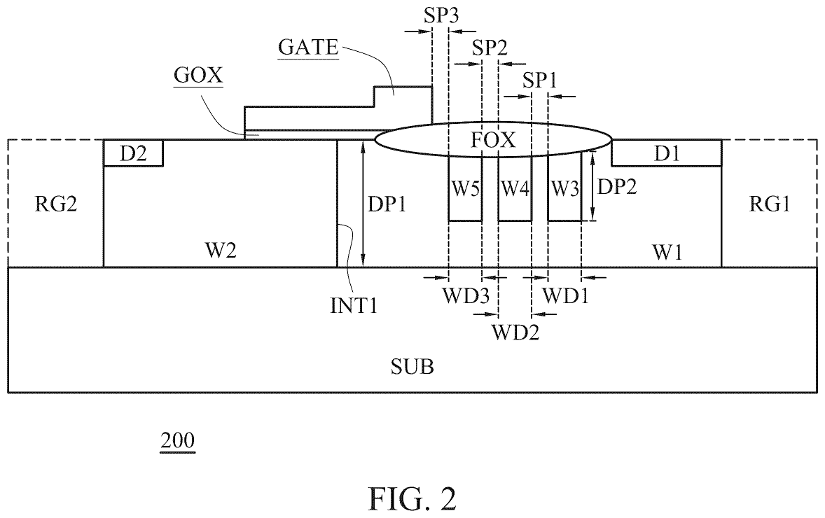

FIG. 2 is a cross-sectional view illustrating a semiconductor structure in accordance with an embodiment of the present invention. According to an embodiment of the present invention, the semiconductor structure 200 is a high-voltage junction termination structure, which corresponds to the junction diode JD in FIG. 1. As shown in FIG. 2, the semiconductor structure 200 includes a substrate SUB, a first well W1, and a second well W2.

The substrate SUB has a first conductivity type. According to an embodiment of the present invention, the substrate SUB is a silicon substrate. According to another embodiment of the present invention, the substrate SUB may be a light-doped semiconductor substrate having a first conductivity type. According to other embodiments of the present invention, the substrate SUB may also be an epitaxial substrate.

The first well W1 is formed in the semiconductor substrate SUB and has a second conductivity type. According to an embodiment of the present invention, the first conductivity type is P-type, and the second conductivity type is N-type. According to an embodiment of the invention, the first well W1 may be formed by ion implantation steps. For example, phosphorus ions or arsenic ions can be implanted in the region where the first well W1 is intended to be formed to form the first well W1 to form the first well W1.

As shown in FIG. 2, the first well W1 is adjacent to the first region RG1. According to some embodiments of the present invention, the high-side driving circuit 130 in FIG. 1 is deposited in the first region RG1. According to some embodiments of the present invention, the level-shift circuit 120 in FIG. 1 may be deposited between the first region RG1 and the second region RG2.

The second well W2 is formed in the semiconductor substrate SUB, adjacent to the first well W1, and in contact with the first well W1 at the first interface INT1. The second well W2 has the first conductivity type. According to an embodiment of the present invention, the second well W2 may also be formed by an ion implantation step. For example, boron ions or indium ions can be implanted in the region where the second well W2 is intended to be formed to form the second well W2. In this embodiment, the doping concentration of the second well W2 is higher than the doping concentration of the semiconductor substrate SUB.

As shown in FIG. 2, the second well W2 is adjacent to the second area RG2. According to some embodiments of the present invention, the low-side driving circuit 110 in FIG. 1 is deposited in the second region RG2. According to some embodiments of the present invention, the level-shift circuit 120 in FIG. 1 may be deposited between the second region RG2 and the first region RG1. According to some embodiments of the present invention, the first region RG1 can be regarded as a high-side region, the second region RG2 can be regarded as a low-side region, and the high-voltage junction terminal structure 200 is configured to isolate the high-side region and the low-side region.

As shown in FIG. 2, the semiconductor structure 200 further includes a first doping region D1 and a second doping region D2. The first doping region D1 has the second conductivity type and is formed in the first well W1. According to an embodiment of the invention, the first doping region D1 may be formed by an ion implantation step. For example, phosphorus ions or arsenic ions can be implanted in the region where the first doping region D1 is intended to be formed to form the first doping region D1. According to an embodiment of the present invention, the doping concentration of the first doping region D1 is higher than the doping concentration of the first well W1.

The second doping region D2 has the first conductivity type and is formed in the second well W2. According to an embodiment of the present invention, the second doping region D2 can also be formed by an ion implantation step. For example, boron ions or indium ions can be implanted in the region where the second doping region D2 is intended to be formed to form the second doping region D2. According to an embodiment of the present invention, the doping concentration of the second doping region D2 is higher than the doping concentration of the second well W2.

As shown in FIG. 2, the semiconductor structure 200 further includes a field oxide layer FOX, a gate oxide layer GOX, and a gate electrode GATE. The field oxide layer FOX is formed in the first well W1 and is adjacent to the first doping region D1. The gate oxide layer GOX covers the first interface INT1 and is formed between the field oxide layer FOX and the second doping region D2. The gate electrode GATE covers the field oxide layer FOX and the gate oxide layer GOX, and is in contact with the gate oxide layer GOX. According to an embodiment of the present invention, part of the gate electrode GATE covers the field oxide layer FOX.

As shown in FIG. 2, the semiconductor structure 200 further includes a third well W3, a fourth well W4, and a fifth well W5. The third well W3 has the second conductivity type and is formed in the first well W1 and adjacent to the first doping region D1, in which the field oxide layer FOX covers the third well W3. According to an embodiment of the present invention, the third well W3 may be formed by an ion implantation step. For example, phosphorus ions or arsenic ions can be implanted in the region where the third well W3 is intended to be formed to form the third well W3. According to an embodiment of the present invention, the doping concentration of the third well W3 is higher than the doping concentration of the first well W1, and the doping concentration of the first doping region D1 is higher than the doping concentration of the third well W3.

The fourth well W4 has a second conductivity type and is formed in the first well W1 and adjacent to the third well W3, where the field oxide layer FOX covers the fourth well W4. According to an embodiment of the present invention, the fourth well W4 may be formed by an ion implantation step. For example, phosphorus ions or arsenic ions can be implanted in the region where the fourth well W4 is intended to be formed to form the fourth well W4. According to an embodiment of the present invention, the doping concentration of the fourth well W4 is higher than the doping concentration of the first well W1, and the doping concentration of the first doping region D1 is higher than the doping concentration of the fourth well W4.

The fifth well W5 has the second conductivity type and is formed in the first well W1 and adjacent to the fourth well W4, where the field oxide layer FOX covers the fifth well W5. According to an embodiment of the present invention, the fifth well W5 may be formed by an ion implantation step. For example, phosphorus ions or arsenic ions can be implanted in the region where of the fifth well W5 is intended to be formed to form the fifth well W5. According to an embodiment of the present invention, the doping concentration of the fifth well W5 is higher than the doping concentration of the first well W1, and the doping concentration of the first doping region D1 is higher than the doping concentration of the fifth well W5.

According to an embodiment of the present invention, the first well W1 has a first depth DP1, the third well W3, the fourth well W4, and the fifth well W5 have a second depth DP2, where the second depth DP2 is not greater than the first depth DP1. As shown in FIG. 2, the third well W3 has a first width WD1, the fourth well W4 has a second width WD2, and the fifth well W5 has a third width WD3. In this embodiment, the first width WD1, the second width WD2, and the third width WD3 are close to one another.

There is a first space SP1 between the third well W3 and the fourth well W4, and there is a second space SP2 between the fourth well W4 and the fifth well W5. According to an embodiment of the present invention, the first space SP1 and the second space SP2 are similar to each other. According to another embodiment of the present invention, the first space SP1 and the second space SP2 are different. According to other embodiments of the present invention, both the first space SP1 and the second space SP2 are zero. In other words, the third well W3, the fourth well W4, and the fifth well W5 can also be wells connected to one another. Three wells are used for explanation herein, but it is not intended to be limited thereto.

As shown in FIG. 2, there is a third space SP3 between the fifth well W5 and the gate electrode GATE, where the third space SP3 is not less than zero. In other words, the gate electrode GATE does not cover any of the third well W3, the fourth well W4, and the fifth well W5. According to some embodiments of the present invention, the third well W3, the fourth well W4, and the fifth well W5 are configured to increase the doping concentration of the first well W1, so as to decrease the breakdown voltage of the first interface INT1 of the semiconductor structure 200.

In other words, when an electrostatic discharge event occurs at the first high voltage VB in FIG. 1, although the junction diode JD, the first N-type transistor N1, and the second N-type transistor N2 have similar structures and are adjacent to one another in the layout, however, the junction diode JD having the third well W3, the fourth well W4, and the fifth well W5 has a lower breakdown voltage, so that the junction diode JD is preferentially turned on to excel the electrostatic charges, thereby protecting the first N-type transistor N1 and the second N-type transistor N2 from burning out.

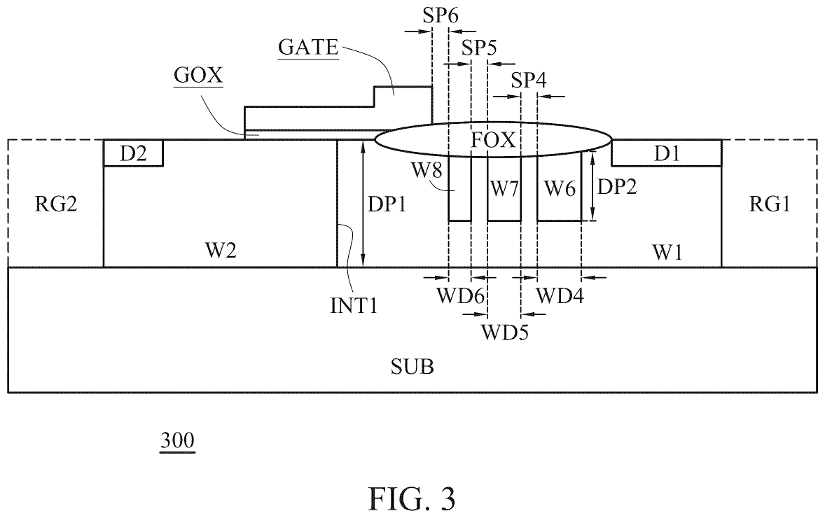

FIG. 3 is a cross-sectional view illustrating a semiconductor structure in accordance with another embodiment of the present invention. According to an embodiment of the present invention, the semiconductor structure 300 is a high-voltage junction termination structure and corresponds to the junction diode JD in FIG. 1. Comparing the semiconductor structure 300 in FIG. 3 with the semiconductor structure 200 in FIG. 2, the third well W3, the fourth well W4, and the fifth well W5 are respectively replaced with the sixth well W6 and the seventh well W7, and the eighth well W8.

The sixth well W6 has a fourth width WD4, the seventh well W7 has a fifth width WD5, and the eighth well W8 has a sixth width WD6. According to an embodiment of the present invention, the fourth width WD4 is greater than the fifth width WD5, and the fifth width WD5 is greater than the sixth width WD6.

As shown in FIG. 3, there is a fourth space SP4 between the sixth well W6 and the seventh well W7, and there is a fifth space SP5 between the seventh well W7 and the eighth well W8. According to an embodiment of the present invention, the fourth interval SP4 and the fifth space SP5 are similar. According to another embodiment of the present invention, the fourth space SP4 and the fifth space SP5 may also be significantly different. There is a sixth space SP6 between the eighth well W8 and the gate electrode GATE, where the sixth space SP6 is not less than zero. In other words, the gate electrode GATE does not cover any of the fourth space SP4, the seventh well W7, and the eighth well W8.

According to some embodiments of the present invention, the sixth well W6, the seventh well W7, and the eighth well W8 are configured to increase the doping concentration of the first well W1, so that the breakdown voltage of the first interface INT1 of the semiconductor structure 300 is reduced. In other words, when an electrostatic discharge event occurs at the first high voltage VB in FIG. 1, the sixth well W6, the seventh well W7, and the eighth well W8 reduce the breakdown voltage of the junction diode JD, so that The electrostatic charge is preferentially discharged to the ground terminal through the junction diode JD, thereby protecting the adjacent first N-type transistor N1 and the second N-type transistor N2 from burning out.

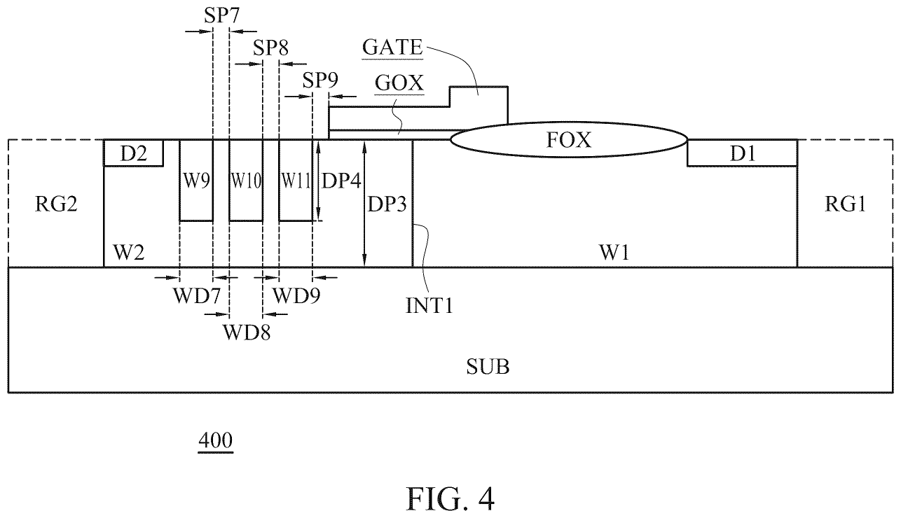

FIG. 4 is a cross-sectional view illustrating a semiconductor structure in accordance with yet another embodiment of the present invention. According to an embodiment of the present invention, the semiconductor structure 400 is a high-voltage junction termination structure and corresponds to the junction diode JD in FIG. 1. Comparing the semiconductor structure 400 of FIG. 4 with the semiconductor structure 200 of FIG. 2, the third well W3, the fourth well W4, and the fifth well W5 deposited in the first well W1 are replaced with those the ninth well W9, the tenth well W10, and the eleventh well W11 deposited in the second well W2.

The ninth well W9 is adjacent to the second doping region D2 and has a seventh width WD7, the tenth well W10 has an eighth width WD8, and the eleventh well W11 has a ninth width WD9. According to an embodiment of the present invention, the seventh width WD7, the eighth width WD8 and the ninth width WD9 are similar.

As shown in FIG. 4, there is a seventh space SP7 between the ninth well W9 and the tenth well W10, and there is an eighth space SP8 between the tenth well W10 and the eleventh well W11. According to an embodiment of the present invention, the seventh interval SP7 and the eighth interval SP8 are similar. According to another embodiment of the present invention, the seventh interval SP7 and the eighth interval SP8 may also be significantly different. There is a ninth interval SP9 between the eleventh well W11 and the gate electrode GATE, where the ninth interval SP9 is not less than zero. In other words, the gate electrode GATE does not cover any of the ninth well W9, the tenth well W10, and the eleventh well W11.

According to an embodiment of the present invention, the second well W2 has a third depth DP3, the ninth well W9, the tenth well W10 and the eleventh well W11 have a fourth depth DP4, where the fourth depth DP4 is no larger than the third depth DP3.

According to some embodiments of the present invention, the ninth well W9, the tenth well W10, and the eleventh well W11 are configured to increase the doping concentration of the second well W2, so that the breakdown voltage of the first interface INT1 of the semiconductor structure 400 is reduced. In other words, when an electrostatic discharge event occurs at the first high voltage VB in FIG. 1, the ninth well W9, the tenth well W10, and the eleventh well W11 reduce the breakdown voltage of the junction diode JD, so that the electrostatic charge is preferentially discharged to the ground terminal through the junction diode JD, thereby protecting the adjacent first N-type transistor N1 and the second N-type transistor N2 from burning out.

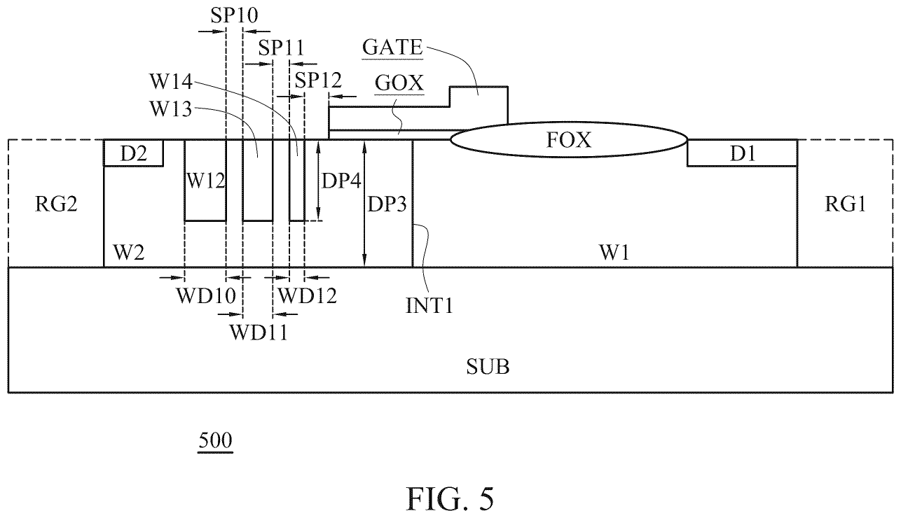

FIG. 5 is a cross-sectional view illustrating a semiconductor structure in accordance with yet another embodiment of the present invention. According to an embodiment of the present invention, the semiconductor structure 500 is a high-voltage junction termination structure and corresponds to the junction diode JD in FIG. 1. Comparing the semiconductor structure 500 in FIG. 5 with the semiconductor structure 400 in FIG. 4, the ninth well W9, the tenth well W10, and the eleventh well W11 are respectively replaced with the twelfth well W12, the thirteenth well W13, and the fourteenth well W14.

The twelfth well W12 has a tenth width WD10, the thirteenth well W13 has an eleventh width WD11, and the fourteenth well W14 has a twelfth width WD12. According to an embodiment of the present invention, the tenth width WD10 is greater than the eleventh width WD11, and the eleventh width WD11 is greater than the twelfth width WD12.

As shown in FIG. 5, there is a tenth space SP10 between the twelfth well W12 and the thirteenth well W13, and there is an eleventh space SP11 between the thirteenth well W13 and the fourteenth well W14. According to an embodiment of the present invention, the tenth space SP10 and the eleventh space SP11 are similar. According to another embodiment of the present invention, the tenth space SP10 and the eleventh space SP11 may also be significantly different. There is a twelfth space SP12 between the fourteenth well W14 and the gate electrode GATE, where the twelfth in space SP12 is not less than zero. In other words, the gate electrode GATE does not cover any of the twelfth well W12, the thirteenth well W13, and the fourteenth well W14.

According to some embodiments of the present invention, the breakdown voltage of the first interface INT1 of the semiconductor structure 500 can be adjusted to an appropriate breakdown voltage through the width and number of the well inserted into the second well W2, thereby ensuring that the junction diode JD in FIG. 1 is preferentially turned on during an electrostatic discharge event.

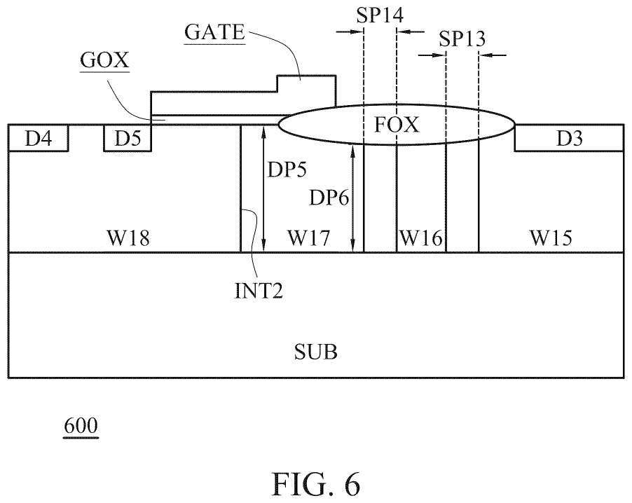

FIG. 6 is a cross-sectional view illustrating a semiconductor structure in accordance with yet another embodiment of the present invention. According to an embodiment of the present invention, the semiconductor structure 600 is a transistor, which corresponds to the first N-type transistor N1 and the second N-type transistor N2 in FIG. 1.

As shown in FIG. 6, the semiconductor structure 600 includes a substrate SUB, a fifteenth well W15, a sixteenth well W16, a seventeenth well W17, and an eighteenth well W18.

The substrate SUB has a first conductivity type. According to an embodiment of the present invention, the substrate SUB is a silicon substrate. According to another embodiment of the present invention, the substrate SUB may be a light-doped semiconductor substrate having a first conductivity type. According to other embodiments of the present invention, the substrate SUB may also be an epitaxial substrate.

The fifteenth well W15, the sixteenth well W16, and the seventeenth well W17 are formed in the semiconductor substrate SUB, and all have the second conductivity type. According to an embodiment of the present invention, the fifteenth well W15, the sixteenth well W16, and the seventeenth well W17 may be formed by an ion implantation step. For example, phosphorus ions or arsenic ions can be implanted in the regions where the fifteenth well W15, the sixteenth well W16, and the seventeenth well W17 are intended to be formed to form the fifteenth well W15, the sixteenth well W16, and the seventeenth well W17 respectively. According to an embodiment of the present invention, the doping concentrations of the fifteenth well W15, the sixteenth well W16, and the seventeenth well W17 are similar.

There is a thirteenth space SP13 between the fifteenth well W15 and the sixteenth well W16, and there is a fourteenth space SP14 between the sixteenth well W16 and the seventeenth well W17. According to an embodiment of the present invention, the thirteenth space SP13 and the fourteenth space SP14 are similar. According to an embodiment of the present invention, the fifteenth well W15, the sixteenth well W16 and the seventeenth well W17 have a fifth depth DP5, and the thirteenth space SP13 and the fourteenth space SP14 have a sixth depth DP6. The fifth depth DP5 and the sixth depth DP6 are similar.

The eighteenth well W18 is formed in the semiconductor substrate SUB, is adjacent to the seventeenth well W17, and is in contact with the seventeenth well W17 at the second interface INT2, where the eighteenth well W18 has the first conductivity type. According to an embodiment of the present invention, the eighteenth well W18 may also be formed by an ion implantation step. For example, boron ions or indium ions may be implanted in the area where the eighteenth well W18 is intended to be formed to form the eighteenth well W18. In this embodiment, the doping concentration of the eighteenth well W18 is higher than the doping concentration of the semiconductor substrate SUB.

As shown in FIG. 6, the semiconductor structure 600 further includes a third doping region D3, a fourth doping region D4, and a fifth doping region D5. The third doping region D3 has the second conductivity type and is formed in the fifteenth well W15. According to an embodiment of the present invention, the third doping region D3 may be formed by an ion implantation step. For example, phosphorus ions or arsenic ions can be implanted in the region where the third doping region D3 is intended to be formed to form the third doping region D3. According to an embodiment of the present invention, the doping concentration of the third doping region D3 is higher than the doping concentration of the fifteenth well W15, the sixteenth well W16, and the seventeenth well W17.

The fourth doping region D4 has the first conductivity type and is formed in the eighteenth well W18. According to an embodiment of the present invention, the fourth doping region D4 may also be formed by an ion implantation step. For example, boron ions or indium ions can be implanted in the region where the fourth doping region D4 is intended to be formed to form the fourth doping region D4. According to an embodiment of the present invention, the doping concentration of the fourth doping region D4 is higher than the doping concentration of the eighteenth well W18.

The fifth doping region D5 has the second conductivity type, is formed in the eighteenth well W18, and is deposited between the third doping region D3 and the fourth doping region D4. According to an embodiment of the present invention, the fifth doping region D5 may be formed by an ion implantation step. For example, phosphorus ions or arsenic ions can be implanted in the region where the fifth doping region D5 is intended to be formed to form the fifth doping region D5. According to an embodiment of the present invention, the doping concentration of the fifth doping region D5 is higher than the doping concentrations of the fifteenth well W15, the sixteenth well W16, and the seventeenth well W17.

As shown in FIG. 6, the semiconductor structure 600 further includes a field oxide layer FOX, a gate oxide layer GOX, and a gate electrode GATE. The field oxide layer FOX is formed in the substrate SUB, the fifteenth well W15, the sixteenth well W16, and the seventeenth well W17, and is adjacent to the third doping region D3, where the field oxide layer FOX is deposited between the third doping region D3 and the fifth doping region D5. The gate oxide layer GOX covers the second interface INT2 and is formed between the field oxide layer FOX and the fifth doping region D5. The gate electrode GATE covers the field oxide layer FOX and the gate oxide layer GOX, and is in contact with the gate oxide layer GOX. According to an embodiment of the present invention, part of the gate electrode GATE covers the field oxide layer FOX.

According to an embodiment of the present invention, the semiconductor structure 600 forms the first N-type transistor N1 and the second N-type transistor N2 in FIG. 1, where the third doping region D3 forms the drain terminal, the gate electrode GATE forms the gate terminal, and the fifth doping region D5 forms the source terminal. According to an embodiment of the present invention, the fifteenth well W15, the sixteenth well W16, and the seventeenth well W17 can be regarded as a virtual well, in which the breakdown voltage of the second interface INT2 is determined by the doping concentrations of the virtual well and the eighteenth well W18.

The thirteenth space SP13 and the fourteenth space SP14 are configured to reduce the doping concentration of the virtual well, thereby increasing the breakdown voltage of the second interface INT2. In other words, when an electrostatic discharge event occurs at the first high voltage VB in FIG. 1, the first N-type transistor N1 and the second N-type transistor N2 having a breakdown voltage higher than that of the junction diode JD prompts the junction diode JD to preferentially break down to expel electrostatic charges, thereby protecting the first N-type transistor N1 and the second N-type transistor N2 from burning out.

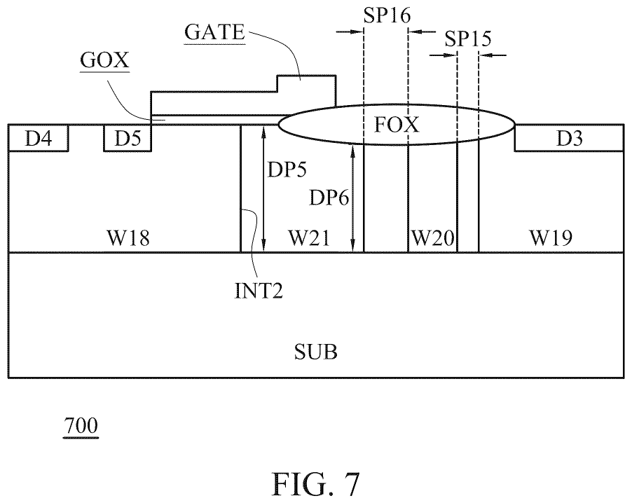

FIG. 7 is a cross-sectional view illustrating a semiconductor structure in accordance with yet another embodiment of the present invention. According to an embodiment of the present invention, the semiconductor structure 700 is a transistor and corresponds to the first N-type transistor N1 and the second N-type transistor N2 in FIG. 1. Comparing the semiconductor structure 700 of FIG. 7 with the semiconductor structure 600 of FIG. 6, the fifteenth well W15, the sixteenth well W16, and the seventeenth well W17 are respectively replaced with the nineteenth well W19, the twenty well W20, and the twenty-first well W21.

As shown in FIG. 7, there is a fifteenth space SP15 between the nineteenth well W19 and the twentieth well W20, and there is a sixteen pitch SP16 between the twentieth well W20 and the twenty-first well W21. According to an embodiment of the present invention, the sixteenth pitch SP16 is larger than the fifteenth pitch SP15.

The fifteenth space SP15 and the sixteenth space SP16 are configured to reduce the doping concentration of the virtual well formed by the fifteenth well W15, the sixteenth well W16, and the seventeenth well W17, so as to increase the breakdown voltage of the second interface INT2. In other words, when an electrostatic discharge event occurs at the first high voltage VB in FIG. 1, the first N-type transistor N1 and the second N-type transistor N2 have a breakdown voltage higher than that of the junction diode JD since the first N-type transistor N1 and the second N-type transistor N2 have a fifteenth space SP15 and the sixteenth space SP16, so as to prompt the junction diode JD to break down preferentially to expel the electrostatic charges, thereby protecting the first N-type transistor N1 and the second N-type transistor N2 from burning out.

The present invention proposes a semiconductor structure of a high-voltage junction terminal structure, which helps to reduce the breakdown voltage of the parasitic diode of the high-voltage junction terminal structure by inserting a well with a higher concentration into the well of the high-voltage junction terminal structure, leading to the electrostatic charge being discharged to the ground through the parasitic diode of the high-voltage junction terminal structure. The present invention further proposes transistors adjacent to the high-voltage junction terminal structure. By inserting a gap into the well of the transistors adjacent to the high-voltage junction terminal structure, the breakdown voltage of the transistors is increased, thereby promoting the parasitic diode of the high-voltage junction termination structure, which is adjacent to the transistors and has a lower breakdown voltage, to preferentially break down to expel the electrostatic charges.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor structure, comprising:
a first well, doped with an N-type dopant;
a second well, doped with a P-type dopant, adjacent to the first well, and in contact with the first well at an interface;
a first doping region, doped with the N-type dopant and deposited in the first well;
a second doping region, doped with the P-type dopant and deposited in the second well;
a field oxide layer, formed in the first well and deposited between the first doping region and the second doping region;
a third well, doped with the N-type dopant, formed in the first well, and deposited below the field oxide layer; and
a fourth well, doped with the N-type dopant, formed in the first well, and deposited below the field oxide layer;
wherein the third well and the fourth well are configured to reduce the breakdown voltage of the interface.

2. The semiconductor structure as defined in claim 1, wherein semiconductor elements in the first region are powered by a first high voltage and a first low voltage, and semiconductor elements in the second region are powered by a second high voltage and a second low voltage;
wherein the first high voltage exceeds the first low voltage, and the second high voltage exceeds the second low voltage;
wherein the first high voltage exceeds the second high voltage;
wherein the second low voltage does not exceed the first low voltage.

3. The semiconductor structure as defined in claim 1, wherein the first well has a first depth, and the third well has a second depth;
wherein the second depth does not exceed the first depth.

4. The semiconductor structure as defined in claim 1, further comprising:
a gate oxide layer, covering the interface and deposited between the first doping region and the second doping region; and
a gate electrode, covering the field oxide layer and the gate oxide layer and in contact with the gate oxide layer;
wherein at least part of the gate oxide electrode covers the field oxide layer.

5. The semiconductor structure as defined in claim 4, wherein the third well has a first width;
wherein the fourth well has a second width;
wherein the first width is not less than the second width.

6. The semiconductor structure as defined in claim 4, wherein there is a first space between the third well and the fourth well;
wherein the third well is adjacent to the first doping region;
wherein the fourth well is adjacent to the gate electrode;
wherein the first space is not less than zero.

7. The semiconductor structure as defined in claim 4, wherein there is a second space between the fourth well and the gate electrode;
wherein the second space is not less than zero.

8. The semiconductor structure as defined in claim 4, further comprising:
a fifth well, doped with the N-type dopant, formed in the first well, and deposited below the field oxide layer, wherein the fifth well is deposited between the fourth well and the gate electrode;
wherein the fifth well has a third width;
wherein the first width is not less than the second width, and the second width is not less than the third width.

9. The semiconductor structure as defined in claim 4, further comprising:
a sixth well, doped with the P-type dopant, formed in the second well, and adjacent to the second doping region; and
a seventh well, doped with the P-type dopant, formed in the second well, and deposited between the sixth well and the gate electrode;
wherein the sixth well and the seventh well are configured to reduce the breakdown voltage of the interface.

10. The semiconductor structure as defined in claim 9, wherein there is a third space between the sixth well and the seventh well;
wherein the third space is not less than zero.

11. The semiconductor structure as defined in claim 9, wherein the sixth well has a fourth width;
wherein the seventh well has a fifth width;
wherein the fourth width is not less than the fifth width.

12. The semiconductor structure as defined in claim 11, further comprising:
an eighth well, doped with the P-type dopant, formed in the second well, and deposited between the seventh well and the gate electrode;
wherein the eighth well has a sixth width;
wherein the fifth width is not less than the sixth width.

13. The semiconductor structure as defined in claim 12, wherein there is a fifth space between the eighth well and the gate electrode;
wherein the fifth space exceeds zero.

14. A semiconductor structure, comprising:
a substrate;
a first well, doped with an N-type dopant and formed in the substrate;
a second well, doped with the N-type dopant, formed in the substrate, and adjacent to the first well, wherein there is a first space between the first well and the second well;
a third well, doped with a P-type dopant, adjacent to the second well, and in contact with the second well at an interface;
a first doping region, doped with the N-type dopant and formed in the first well;
a second doping region, doped with the P-type dopant and formed in the third well;
a third doping region, doped with the N-type dopant, formed in the third well, and deposited between the first doping region and the second doping region; and
a field oxide layer, covering the first well, the second well, and the substrate and deposited between the first doping region and the third doping region;
wherein the first space is configured to increase the breakdown voltage of the interface.

15. The semiconductor structure as defined in claim 14, wherein the semiconductor structure forms a transistor.

16. The semiconductor structure as defined in claim 14, further comprising:
a gate oxide layer, covering the interface and deposited between the first doping region and the third doping region; and
a gate electrode, covering the field oxide layer and the gate oxide layer and in contact with the gate oxide layer;
wherein at least part of the gate electrode covers the field oxide layer;
wherein the semiconductor forms a transistor.

17. The semiconductor structure as defined in claim 14, further comprising:
a fourth well, doped with the N-type dopant, formed in the substrate, and deposited between the second well and the third well;
wherein the fourth well is in contact with the third well at the interface;
wherein there is a second space between the fourth well and the second well.

18. The semiconductor structure as defined in claim 17, wherein the second space exceeds the first space.

19. The semiconductor structure as defined in claim 17, wherein the second space is equal to the first space.

20. The semiconductor structure as defined in claim 17, wherein there is a gap between the second well and the fourth well;
wherein the width of the gap is the second space;
wherein there is a third space between the gap and the gate electrode;
wherein the third space exceeds zero.
